(19) United States
(12) Patent Application Publication
(10) Pub. No.: US 2008/0106275 A1
(43) Pub. Date: May 8, 2008

(54) Sensor and Method for Measuring a Variable Affecting a Capacitive Component

(75) Inventors: Heikki Seppa, Helsinki (FI); Hannu Sipola, Klaukkala (FI)

Correspondence Address: BIRCH STEWART KOLASCH & BIRCH, PO BOX 747, FALLS CHURCH, VA, 22040-0747, US

(73) Assignee: VALTION TEKNILLINEN TUTKIMUSKESKUS, Espoo (FI)

(21) Appl. No.: 11/665,386

(22) PCT Filed: Oct. 14, 2005
(86) PCT No.: PCT/FI05/00448

§ 371 Date: Aug. 13, 2007

(30) Foreign Application Priority Data
Oct. 15, 2004 (FI) 20041344

(51) Int. Cl. G01R 27/26

(52) U.S. Cl. 324/680

(57) ABSTRACT

The invention relates to a sensor and method for measuring a variable affecting a micro-electromechanical component. The invention is based on creating electronics, which are preferably integrated in a single circuit and which exploit the pull-in point of a micro-electromechanical sensor component such as a direct-current reference, for measuring a variable affecting the sensor, in which case an alternating or a direct-current is arranged over the sensor with the aid of a feedback connection, so that the arrangement operates very close to the pull-in point of the sensor.

The present invention relates to a sensor, according to the preamble of claim 1, and a method, according to the preamble of claim 13, for measuring a variable affecting a micro-electromechanical component.

In methods according to the prior art, the noise detected by measuring sensors is often limited by the noise caused by the electronics. If the sensor capacitance varies as a function of time, it is simple to apply charge or voltage-level biasing and read the variable voltage or charge bias over the micro-electromechanical (MEMS, Micro Electro Mechanical Systems) electrodes using, for example, a CMOS or JFET amplifier.

Micro-electromechanics is the integration of mechanical elements, sensors, electronics, and possibly operating power on a common silicon substrate, using a micro-manufacturing technology. Integrated-circuit process series, such as CMOS, Bipolar, or BICMOS processes, are used in the manufacture of electronics. When manufacturing micromechanical components, micro-machining processes are used, which selectively etch away parts of the silicon board, or add new structural layers, to create mechanical and electromechanical devices.

Micro-electromechanics permits innovations in various product sectors by uniting microelectronics and micro-machining technology on a single silicon base. These can be used to implement entire systems on single chips. Micro-electromechanics can be used to develop intelligent products, which have the computing ability brought by microelectronics and the precision and control properties of micro-sensors. On the basis of these, new applications can be designed. The sensors can collect data from the environment, by measuring mechanical, thermal, biological, chemical, optical, and magnetic conditions, and the electronics can include control logic operating in response to them, which acts to control the physical components of the system.

A drawback in the prior art is that in force-balance measurement, when the magnitude of the sensor capacitance is constant, the measurement using the reading electronics cannot be implemented in such a way that mechanical noise would be the dominant type of noise. The change in the variable being measured must therefore be read by using alternating current to measure the change in capacitance, whereby the alternating current measurement will also minimize the 1/f noise of the amplifier.

Although the use of alternating current often achieves less total noise, the noise caused by the electronics limits the noise detected by the sensor. If we tune the capacitance using a coil and noise-optimize the preamplifier correctly, we can by using a separate circuit achieve a situation, in which mechanical noise is dominant. This is, however, difficult, nor can the coil be integrated in the reading-electronics' integrated circuit.

The invention is intended to create an entirely new type of method and means for arranging measurement in force-balance measurement, when then sensor capacitance is of a constant magnitude, in such a way that the dominant type of noise is mechanical noise.

The present publication discloses a method according to the invention, in which an alternating or a direct-current signal is used to read micro-electromechanical sensor capacitance. The measurement is performed using a bridge circuit. The other capacitances required by the bridge can be integrated either in connection with the micro-electromechanical sensor, or in an integrated circuit. Hereinafter, the capacitance, which is in the same measuring branch as the sensor capacitance, will be referred to as the reference capacitance.

The invention is based on creating electronics, which are preferably integrated in a single circuit and which exploit the pull-in point of a micro-electromechanical sensor component such as a direct-current reference, for measuring a variable affecting the sensor, in which case an alternating or a direct-current voltage is arranged over the sensor with the aid of a feedback connection, so that the arrangement operates very close to the pull-in point of the sensor.

More specifically, the sensor according to the invention is characterized by what is stated in the characterizing portion of claim 1. The method according to the invention is, in turn, characterized by what is stated in the characterizing portion of claim 13.

Considerable advantages are gained with the aid of the invention. In force-balance measurement, when the capacitance of the sensor is essentially of constant magnitude, the measurement by using the reading electronics can be implemented in such a way that the dominant type of noise is mechanical noise.

A preferred embodiment of the invention is the application of the method in microphones, sensitive pressure sensors, MEMS-based microwave power measurements, and similar. An essential feature of the method is that it permits the use of insensitive electronics, without a special tuned circuit used for noise adjustment, and despite this the noise of the system is mainly limited to the mechanical noise of the component. The preferred solution is created, if the reference capacitance is inside the same micro-electromechanical component and its temperature coefficient is the same as the temperature coefficient of the sensor capacitance.

In the following, the invention is examined with the aid of examples and with reference to the accompanying drawings.

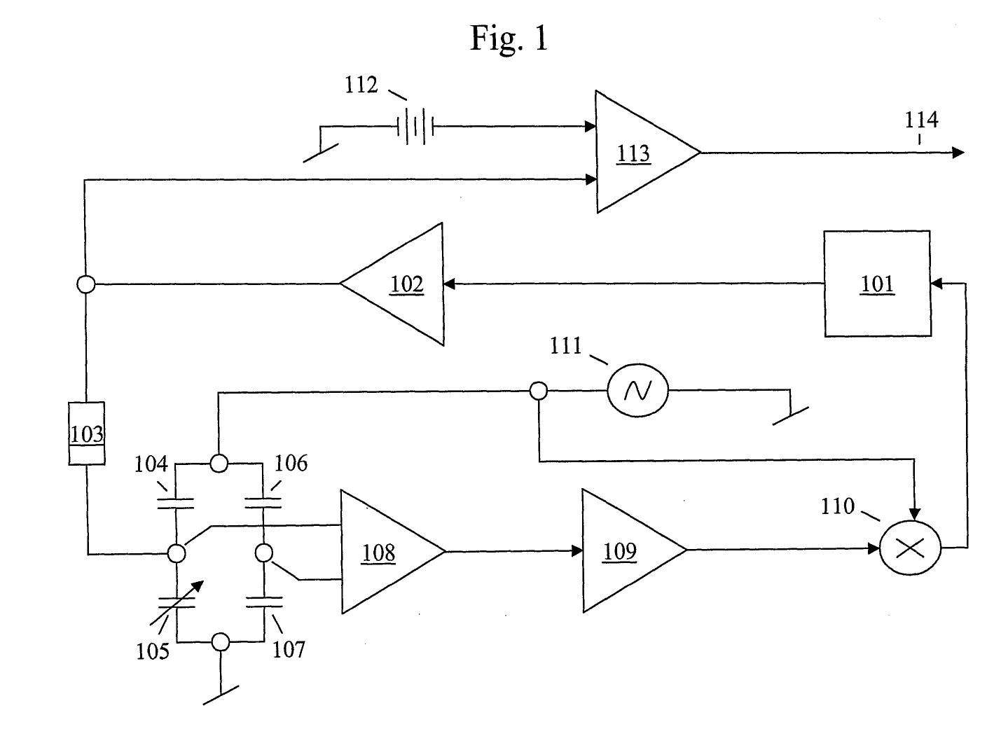

FIG. 1 shows a circuit scheme of one electronic circuit according to the invention for measuring a variable affecting a component.

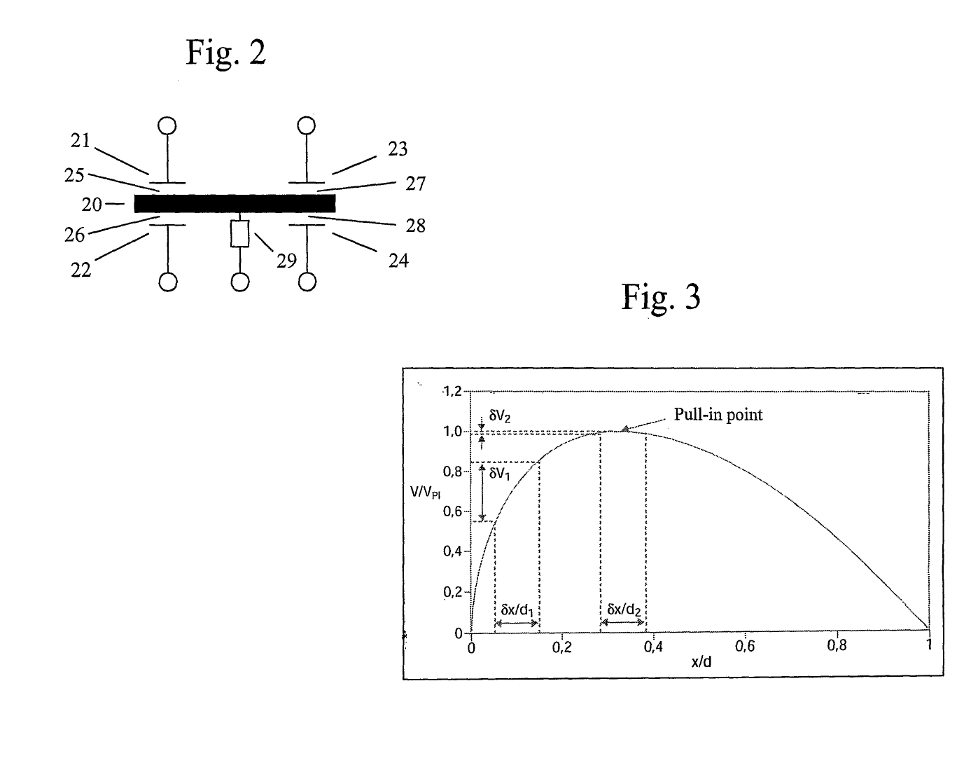

FIG. 2 shows one known sensor component, a direct-current reference flip-flop, which can be used in the method and sensor according to the invention.

FIG. 3 shows the operating characteristic of the sensor flip-flop according to FIG. 3.

The circuit according to FIG. 1 has the following components. The regulator 101 regulates the output signal transmitted through the first operation amplifier 102. The first operation amplifier 102 transmits the signal that it has received from the regulator 101 and amplified, in the output 114 direction. The resistance 103 is set to adjust the circuit impedance as desired. The reference capacitance 104 is a capacitance, the magnitude of which is known, which acts as a reference value. The sensor capacitance 105 is a capacitance set according to the value of the measured variable. The bridge capacitances 106 and 107 are capacitances that implement the bridge circuit used in measurement. The second operation amplifier 108 receives the difference in potential between the points A and B and transmits the signal to the input of the third operation amplifier 109. The third operation amplifier 109 amplifies the signal it receives from the direction of the operation amplifier 108 and transmits it in the direction of the phase-sensitive detector 110. The phase-sensitive detector 110 expresses the difference between the signal it receives and the alternating voltage that acts as a reference as a direct-voltage signal that changes slowly over time. The fourth operation amplifier 113 compensates the signal sent to the output 114 of the dc-component, in order to create an output of the desired shape. The phase-sensitive detector 110 is a detector element that is adapted to the measurement requirement being performed. The alternating-voltage source 111 is a voltage supply that provides the alternating-current voltage required by the measurement circuit. The direct-voltage source 112 is a direct-current voltage source used to adjust the offset of the amplifier 113.

The circuit according to FIG. 1 operates in the following manner. A capacitive sensor is used to measure a mechanical variable. The sensor capacitance 105 seeks to set according to the measured variable. However, the change in the sensor capacitance alters the difference in potential between the points A and B and thus sends a signal comprising an ac-component in the direction of the operation amplifier 108. The signal is amplified in the operation amplifiers 108 and 109, after which the phase-sensitive detector sends a direct-current signal in the direction of the regulator 101. The regulator 101 interprets the signal and sends a direct-current or an alternating-current signal to the operation amplifier 102, which attempts to produce a control signal neutralizing the difference in potential between the points A and B. The control signal is feedback coupled to the bridge circuit to resist the change in the sensor capacitance 105. The same signal is sent to the circuit's output 114, as a dc-compensated indicator of the measurement result.

In the sensor flip-flop applied to the invention according to FIG. 2, there are the following components. A beam 20, electrodes from the first to the fourth 21-24, which form corresponding capacitors from the first to the fourth 25-28. In addition, there is a resistance 30 in the flip-flop.

The operation of a known dc-voltage reference is based on a sensor flip-flop made from silicon. This micro-electromechanical component is formed of a beam 20 suspended from the centre, at both sides of both ends of which there are metallized electrodes from the first to the fourth 21-24. Thus the flip-flop forms, together with the base and cover plates, four plate capacitors, from the first to the fourth 25-28. When a voltage is fed to one side of the flip-flop, it tilts. The flip-flop is tilted by always increasing the control voltage, up to the point at which it almost clicks onto the other edge. This point is called the pull-in point. The output voltage of the circuit can never exceed the maximum value of the pull-in point, which depends only on the spring constant k of the flip-flop, the distance d between the capacitor plates, the surface area A of the capacitor plates, and the permittivity constant ε of the filling gas, for example, according to FIG. 3.

The tilt is read form the other side of the flip-flop. If the flip-flop moves away from the pull-in point, the voltage division implemented with the aid of the capacitors 27 and 28 is no longer in balance, but causes a current, which is amplified, detected by the mixer, and taken to the control-voltage regulator. The resistance 30 is set to stabilize the circuit. Preferably, in the method according to the invention operation takes place close to the aforesaid pull-in point.

In the operating characteristic of the sensor according to FIG. 3, the output voltage V is shown as a function of the deviation of the flip-flop. Vₚᵢ is the pull-in voltage and d is the air gap between the capacitor plates, when V=0 and x=0.

The following presents the mathematical basis of the invention:

The dynamics of a micromechanical component can be described with the aid of the following equation

$$m \frac{d {}^{2} x}{d {t}^{2}} + η \frac{d x}{d t} + k ( x + {x}_{0} ) = \frac{1}{2} \frac{ɛ A}{{( l - x - {x}_{0} )}^{2}} {( {U}_{ac} + {U}_{dc} + u )}^{2} + F + n ( t ) \qquad ( 1 )$$

in which m is the mass, k is the spring constant, A the surface area of the moving part, η is in general the friction coefficient arising from the gas, F is the force caused by the variable being measured, x is the positional displacement of the membrane, x₀ is the positional displacement caused by the “operating voltage”, U_{ac} is the alternating-current voltage acting over the MEMS component, U_{dc} is in this case the direct-current voltage acting over the circuit and determined by the feedback coupling, and u is the feedback-coupled voltage, which compensates for the changes in the variable being measured. The feedback-coupled voltage can be a dc or ac signal, but in this text it is assumed to be a slowly time-dependent direct-current voltage. ζ is the air gap of the component de-energized energized and in a state of rest, and n(t) is the noise due to friction. The autocorrelation function of the noise can be given in the form [symbol] n(t)n(t+τ) [symbol] =2k_{B}Tηδ(τ). The force F arises from the variable being measured, which can be pressure p (F=pA) or acceleration a (F=ma), or a voltage independent of the feedback-coupled voltage and the voltage used in the measurement, for example, a microwave-frequency voltage.

It is important to note, that in the electronics according to the invention, the micromechanical component is feedback coupled by bringing either a dc or an ac signal from the output of the electronics, which creates a force that compensates the force caused by the variable being measured. Without feedback coupling the system will not necessarily be stable. If the equation is linearized in relation to both position and voltage we get

$$m \frac{d {}^{2} x}{d {t}^{2}} + η \frac{d x}{d t} + ( k - \frac{ɛ A ( {U}_{ac}^{2} + {U}_{dc}^{2}}{{( l - {x}_{0} )}^{2}} ) x = \frac{ɛ A ( {U}_{ac}^{2} + {U}_{dc}^{2} + 2 u ( t ) {U}_{dc} )}{2 ( l - {x}_{0} )} - {kx}_{0} + F ( t ) + n ( t ) \qquad ( 2 )$$

We will note that the effective spring constant depends on the “operating voltage”. We will next assume that the reference capacitance C₀ has been selected in such a way that, when using feedback-coupling, we end up close to the so-called pull-in point. The invention is based on our arranging, with the aid of the feedback coupling, an ac or dc voltage over the component, in such a way that the system operates very close to the so-called pull-in point. At, or close to this operating point, the effective spring constant is zero, i.e.

$$k - \frac{ɛ A ( {U}_{ac}^{2} + {U}_{dc}^{2} )}{{( l - {x}_{0} )}^{2}} = 0$$

This leads us to select

$${C}_{0} = \frac{3}{2} C = \frac{3}{2} ɛ A / l .$$

### At this operating point U²_{ac}+U²_{ad}=U²_{Pi}, and x₀=Λ/3. By using these values, the equation simplifies to the form

$$m \frac{d {}^{2} x}{d {t}^{2}} + η \frac{d x}{d t} = F ( t ) + n ( t ) + \frac{3 ɛ A}{2 l} {U}_{dc} u ( t ) \qquad ( 3 )$$

After a Fourier transformation we obtain

$$ω ( jη - ω m ) X ( j ω ) = F ( j ω ) + N ( j ω ) + \frac{3}{2} {CU}_{dc} U ( j ω ) \qquad ( 4 )$$

Because the force feedback coupling keeps the position of the membrane constant (X(jω)=0), we get for the Fourier transformation of the feedback-coupling voltage the value

$$U ( jω ) = - \frac{2}{3 {CU}_{dc}} [ F ( j ω ) + N ( jω ) + ω ( ω m - j n ) {X}_{n} ( j ω ) ] \qquad ( 5 )$$

in which Xₙ(jω) is the uncertainty of the position measurement depending on the noise of the electronics. We can write the above equation in the form

$$U ( jω ) = - \frac{2}{3 {CU}_{dc}} ( F ( jω ) + ( N ( jω ) + k ( \frac{ω}{{ω}_{res}} ) ( \frac{ω}{{ω}_{res}} + \frac{1}{{Q}_{m}} ) {X}_{n} ( jω ) ) ) \qquad ( 6 )$$

From the equation, the effective measurable force fluctuation can further be expressed in the form

$${S}_{F} = {S}_{n} + {{k}^{2} ( \frac{ω}{{ω}_{res}} )}^{4} ω ( 1 + \frac{1}{{Q}_{m}^{2}} ) {S}_{x} \qquad ( 7 )$$

in which SF is the power density of the effective force fluctuation of the object being measured, Sₙ=4k_{B}Tη=4k_{B}Tk/(ωᵣₑₛQₘ) is the power density of the noise caused by the friction of the MEMS component and S_{X} is the power density of the uncertainty of the position measurement. In this case, the uncertainty of the position measurement depicts the noise of the contribution of the electronics. If the frequency of the signal being measured is clearly smaller than the resonance frequency, we obtain

$${S}_{F} \approx \frac{k}{{ω}_{res} {Q}_{m}} [ 4 {k}_{B} T + {Q}_{m} {ω}_{res} {k ( \frac{ω}{{ω}_{res}} )}^{4} {S}_{x} ] , if {Q}_{m} >> 1 and$$

$${S}_{F} \approx \frac{k}{{ω}_{res} {Q}_{m}} [ 4 {k}_{B} T + \frac{{ω}_{res} k}{{Q}_{m}} {( \frac{ω}{{ω}_{res}} )}^{4} {S}_{x} ] , if {Q}_{m} << 1$$

It will be seen from the equation that, at low signal frequencies, the effective “force fluctuation” is determined only from the mechanical friction. In addition, it will be seen that, if the mechanical quality factor is large, the electronics' noise will be very small. On the other hand, it is very difficult to make the system stable, if the mechanical quality factor is too large.

It is important to note that, when we are at the MEMS pull-in point, or use a higher voltage, the system is mechanically unstable. Due to the electrical force-feedback coupling, the system as a totality is, however, stable. This can be explained by the fact that the electrical feedback coupling effectively creates a positive mechanical spring and the system as a totality is thus stable. The feedback coupling can, however, oscillate, particularly if the mechanical quality factor is especially large. This means that, in practice, the exploitation of the pull-in point to increase the mechanical amplification will be easier, if the mechanical system is well attenuated. Of course, this will increase the mechanical noise.

Within the scope of the invention it is also possible to envisage solutions differing from the embodiment described above. If necessary, the sensor according to the invention can also be applied to the measurement of thermal, biological, chemical, optical, and magnetic conditions.

1. Sensor for measuring a variable affecting a micro-electromechanical component, characterized in that the sensor comprises
electronics, which are integrated in a single circuit and
the sensor is arranged to exploit the pull-in point of a micro-electromechanical sensor component, for measuring a variable affecting the sensor,
whereby an alternating or a direct-current voltage is arranged over the sensor with the aid of a feedback connection, so that the arrangement operates very close to the pull-in point of the sensor, and
force-balance measurement is applied, whereby the capacitance of the sensor is kept essentially in constant magnitude.

2. Sensor in accordance with claim 1 for measuring a variable affecting a micro-electromechanical component, characterized in that it comprises:
an essentially capacitive micro-electromechanical bridge circuit in a single integrated circuit comprising a micro-electromechanical sensor capacitance (105), which bridge circuit comprises:
a first (106) and a second (107) bridge capacitance connected in series, and,
along with them a reference capacitance (104) and a sensor capacitance (105) connected in series.

3. Sensor according to claim 2, characterized in that
the alternating-current or direct-current voltage over the sensor is arranged to be dimensioned with the aid of a feedback coupling, in such a way that the system operates very close to the pull-in point of the sensor capacitance (105), in which case mechanical noise will be the dominant type of noise in the measuring system,
the bridge circuit is arranged to be held in a force balance using a control current, in such a way that the potential of a point A between the sensor capacitance (105) and the reference capacitance (104) essentially corresponds to the potential of a point B between the bridge capacitances, and
the variable affecting the sensor is arranged to be interpreted on the basis of the control current.

4. Sensor according to any of claims 2-3, characterized in that it is arranged to measure pressure, acceleration, microwave power, thermal, biological, chemical, optical, or magnetic conditions.

5. Sensor according to any of claims 2-4, characterized in that it is arranged as a micro-electromechanical microphone, power meter, pressure sensor, acceleration sensor, thermometer, pH-meter, or magnetic-field meter.

6. Sensor according to any of claims 2-5, characterized in that the sensor capacitance (105) comprises a direct-current voltage reference.

7. Direct-current voltage reference according to claim 6, characterized in that it comprises a sensor flip-flop (20-29).

8. Sensor according to any of claims 2-6, characterized in that the sensor capacitance (105) is arranged to be held essentially constant.

9. Sensor according to any of claims 2-7, characterized in that the sensor is integrated in the IC circuit of the reading electronics of the measuring system.

10. Sensor according to any of claims 2-8, characterized in that it is feedback coupled by bringing either a dc or an ac signal from the output (102) of the electronics, which is arranged to create a force compensating the force caused by the variable being measured.

11. Sensor according to any of claims 2-9, characterized in that the other capacitances (104, 106, 107) required by the bridge of the bridge circuit are integrated in connection with the sensor component (105) and/or with the IC circuit, to which the sensor component is attached.

12. Sensor according to any of claims 2-10, characterized in that the measuring system comprising the sensor is arranged to measure insensitive electronics without a special circuit tuned for noise adjustment, in which case the dominant type of noise in the measuring system comprising the sensor is mechanical noise.

13. Sensor according to any of claims 2-11, characterized in that the reference capacitance (104) is inside the sensor component and/or its temperature coefficient is the same as the temperature coefficient of the sensor capacitance (105).

14. Method for measuring a variable affecting a micro-electromechanical component, characterized in that in it measurement takes place:
with help of electronics, which are integrated in a single circuit and
the sensor exploits the pull-in point of a micro-electromechanical sensor component, for measuring a variable affecting the sensor,
whereby an alternating or a direct-current voltage is arranged over the sensor with the aid of a feedback connection, so that the arrangement operates very close to the pull-in point of the sensor, and
force-balance measurement is applied, whereby the capacitance of the sensor is kept essentially in constant magnitude.

15. Method for measuring a variable affecting a micro-electromechanical component, characterized in that in it measurement takes place:
using an essentially capacitive micro-electromechanical bridge circuit in a single integrated circuit comprising a micro-electromechanical sensor capacitance (105), which bridge circuit comprises:
a first (106) and a second bridge capacitance (107) connected in series, and
along with them a reference capacitance (104) and a sensor capacitance (105) connected in series.

16. Method according to claims 15, characterized in that
the alternating-current or direct-current voltage over the sensor is dimensioned with the aid of a feedback coupling in such a way that the system operates very close to the pull-in point of the sensor capacitance (105), so that mechanical noise is the dominant type of noise in the measuring system,
the bridge circuit is held in a force balance using a control current, in such a way that the potential of a point A between the senor capacitance (105) and the reference capacitance (104) essentially corresponds to the potential of a point B between the bridge capacitances, and
the variable affecting the sensor is arranged to be interpreted on the basis of the control current.

17. Method according to any of claims 15-16 characterized in that pressure, acceleration, microwave power, thermal, biological, chemical, optical, or magnetic conditions are measured.

18. Method according to any of claims 15-17, characterized in that the sensor is used as a micro-electromechanical microphone, power meter, pressure sensor, acceleration sensor, thermometer, pH-meter, or magnetic-field meter.

19. Method according to any of claims 15-18, characterized in that the sensor capacitance (105) comprises a direct-current voltage reference.

20. Direct-current voltage reference according to claim 19, characterized in that it comprises a sensor flip-flop (20-29).

21. Method according to any of claims 15-20, characterized in that the sensor capacitance (105) is arranged to be held essentially constant.

22. Method according to any of claims 15-21, characterized in that the sensor is integrated in the IC circuit of the reading electronics of the measuring system.

23. Method according to any of claims 15-22, characterized in that it is feedback coupled by bringing either a dc or an ac signal from the output (102) of the electronics, which is arranged to create a force compensating the force caused by the variable being measured.

24. Method according to any of claims 15-23, characterized in that the other capacitances (104, 106, 107) required by the bridge of the bridge circuit are integrated in connection with the sensor component (105) and/or with the IC circuit, to which the sensor component (105) is attached.

25. Method according to any of claims 15-24, characterized in that the measuring system comprising the sensor is arranged to measure insensitive electronics without a separate circuit tuned for noise adjustment, whereby the dominant type of noise in the measuring system comprising the sensor is mechanical noise.

26. Method according to any of claims 15-25, characterized in that the reference capacitance (104) is inside the sensor component and/or its temperature coefficient is the same as the temperature coefficient of the sensor capacitance (105).
